(19) United States
(12) Patent Application Publication
(10) Pub. No.: US 2025/0275024 A1
(43) Pub. Date: Aug. 28, 2025

(54) ANTENNA UNIT AND SUBSTRATE PROCESSING APPARATUS

(71) Applicant: SEMES CO., LTD., Cheonan-si (KR)

(72) Inventors: Han Lim KANG, Cheonan-si (KR); Sung Suk WI, Cheonan-si (KR); Yoon Seok CHOI, Cheonan-si (KR)

(73) Assignee: SEMES CO., LTD., Cheonan-si (KR)

(21) Appl. No.: 19/064,574

(22) Filed: Feb. 26, 2025

(30) Foreign Application Priority Data
Feb. 27, 2024 (KR) 10-2024-0028407

(51) Int. Cl. H05B 6/72; C23C 16/511; C23C 16/52; F27B 17/00; F27D 11/12; F27D 19/00; H05B 6/64; H05B 6/80

(52) U.S. Cl. CPC H05B 6/72; C23C 16/511; C23C 16/52; F27B 17/0025; F27D 11/12; F27D 19/00; H05B 6/6455; H05B 6/80; F27D 2019/0003

(57) ABSTRACT

Disclosed are an antenna unit for performing a heat treatment process using microwaves and a substrate processing apparatus including the same. The antenna unit has a plurality of wave emission apertures formed therein to emit microwaves toward a substrate disposed below the antenna unit. At least one emission aperture among the plurality of wave emission apertures is provided as a variable emission aperture capable of controlling an emission range of the microwaves.

### CROSS-REFERENCE TO THE RELATED APPLICATION

The present application claims priority to and the benefit of Korean Patent Application No. 10-2024-0028407, filed on Feb. 27, 2024, in the Korean Intellectual Property Office, the entire disclosure of which is herein incorporated by reference.

### BACKGROUND

### 1. Field

Embodiments of the present disclosure relate to an antenna unit, which radiates microwaves to a substrate in order to perform a heat treatment process using microwaves as a substrate processing process, and a substrate processing apparatus including the same.

### 2. Description of the Related Art

There has been proposed a substrate processing apparatus that radiates microwaves to a substrate, such as a semiconductor wafer, in order to perform heat treatment on the substrate.

In general, a substrate processing apparatus that performs a heat treatment process using microwaves includes a process chamber defining a substrate processing space therein, a microwave applying unit, and an antenna made of a conductive material to supply microwaves from the microwave applying unit to the substrate processing space. The microwaves propagate along the antenna. The antenna is formed to have a plurality of wave emission apertures formed therein to emit the propagating microwaves downwards therethrough so that the microwaves are radiated to the substrate located below the antenna.

FIGS. 1A and 1B are partial cross-sectional views showing an antenna applied to a general substrate processing apparatus. Referring to FIG. 1A, wave emission apertures 2a in the antenna 1 may be provided as holes penetrating the antenna 1 in a vertical direction. For example, these holes 2a may have a slot shape. Alternatively, referring to FIG. 1B, wave emission apertures 2b in the antenna 1 may be provided as a groove concavely formed in the lower surface of the antenna 1.

However, if conditions of a heat treatment process are changed, the above conventional antenna 1 is not capable of appropriately changing the microwave emission range through the wave emission apertures 2a or 2b in response to the change in the conditions of the process. Therefore, the conventional antenna must be replaced with a new antenna manufactured in consideration of the changed process conditions. This leads to a great waste of resources.

### RELATED ART DOCUMENT

### Patent Document

(Patent Document 1) Korean patent Laid-Open Publication No. 10-2022-0169010 (Dec. 27, 2022)
(Patent Document 2) Korean patent Laid-Open Publication No. 10-2023-0160095 (Nov. 23, 2023)

### SUMMARY

Embodiments of the present disclosure provide an antenna unit capable of precisely adjusting the range of microwaves emitted from wave emission apertures for a heat treatment process and a substrate processing apparatus including the antenna unit.

The objects to be accomplished by the disclosure are not limited to the above-mentioned object, and other objects not mentioned herein will be clearly understood by those skilled in the art from the following description.

According to an embodiment of the present disclosure, an antenna unit includes an antenna having a plurality of wave emission apertures formed therein to emit microwaves for heat treatment of a substrate toward the substrate located below the antenna and an adjustment plate configured to control an emission range of the microwaves through movement thereof relative to at least one emission aperture among the plurality of wave emission apertures, wherein the emission aperture is provided as a variable emission aperture by the adjustment plate.

The adjustment plate may be provided at the antenna so as to be horizontally movable and to control the emission range of the microwaves by partially shielding the emission aperture or releasing partial shielding of the emission aperture in accordance with a horizontal movement direction thereof. The adjustment plate may be made of a conductive material. Depending on implementation conditions, the adjustment plate may be made of a non-conductive material.

The adjustment plate may be inserted into a wall of the emission aperture so as to be horizontally movable. Alternatively, the adjustment plate may be coupled to a lower surface of the antenna so as to be horizontally movable. Alternatively, the adjustment plate may include a first unit plate coupled to a lower surface of the antenna so as to be horizontally movable and a second unit plate coupled to a lower surface the first unit plate so as to be horizontally movable in a horizontal movement direction of the first unit plate.

The horizontally movable adjustment plate may include two adjustment plates. The two adjustment plates may be disposed on both sides of the emission aperture so as to be opposite each other.

According to an embodiment of the present disclosure, an antenna unit includes an antenna having a plurality of wave emission apertures formed therein to emit microwaves for heat treatment of a substrate toward the substrate located below the antenna and an adjustment plate configured to control an emission range of the microwaves through movement thereof relative to at least one emission aperture among the plurality of wave emission apertures, wherein the emission aperture is provided as a variable emission aperture by the adjustment plate, and the adjustment plate is provided at the antenna so as to be horizontally movable and to control the emission range of the microwaves by partially shielding the emission aperture or releasing partial shielding of the emission aperture in accordance with a horizontal movement direction thereof. To this end, the adjustment plate includes an open area formed corresponding to the emission aperture and a shielding area formed around the open area.

According to an embodiment of the present disclosure, an antenna unit includes an antenna having a plurality of wave emission apertures formed therein to emit microwaves for heat treatment of a substrate toward the substrate located below the antenna and an adjustment plate configured to control an emission range of the microwaves through movement thereof relative to at least one emission aperture among the plurality of wave emission apertures, wherein the emission aperture is provided as a variable emission aperture by the adjustment plate, and the adjustment plate is provided at the antenna so as to be vertically movable and to control the emission range of the microwaves by moving away from or toward the emission aperture in accordance with a vertical movement direction thereof.

The vertically movable adjustment plate may be coupled to a lower surface of the antenna so as to be vertically movable.

The vertically movable adjustment plate may include two adjustment plates, and the two adjustment plates may be disposed on both sides of the emission aperture so as to be opposite each other.

According to an embodiment of the present disclosure, an antenna unit includes an antenna having a plurality of wave emission apertures formed therein to emit microwaves for heat treatment of a substrate toward the substrate located below the antenna and an adjustment plate configured to control an emission range of the microwaves through movement thereof relative to at least one emission aperture among the plurality of wave emission apertures, wherein the emission aperture is provided as a variable emission aperture by the adjustment plate, and the adjustment plate is provided at the antenna so as to be vertically movable and to control the emission range of the microwaves by moving away from or toward the emission aperture in accordance with a vertical movement direction thereof, and includes an open area aligned with the emission aperture.

According to an embodiment of the present disclosure, an antenna unit includes an antenna having a plurality of wave emission apertures formed therein to emit microwaves for heat treatment of a substrate toward the substrate located below the antenna and an adjustment plate configured to control an emission range of the microwaves through movement thereof relative to at least one emission aperture among the plurality of wave emission apertures, wherein the emission aperture is provided as a variable emission aperture by the adjustment plate, and the adjustment plate includes a first unit plate provided at the antenna so as to be horizontally movable and to partially shield the emission aperture or release partial shielding of the emission aperture in accordance with a horizontal movement direction thereof and a second unit plate provided on a lower surface of the first unit plate so as to be vertically movable and to move away from or toward the first unit plate in accordance with a vertical movement direction thereof.

According to an embodiment of the present disclosure, an antenna unit includes an antenna having a plurality of wave emission apertures formed therein to emit microwaves for heat treatment of a substrate toward the substrate located below the antenna, an adjustment plate configured to control an emission range of the microwaves through movement thereof relative to at least one emission aperture among the plurality of wave emission apertures, and a plate drive module configured to move the adjustment plate relative to the emission aperture, wherein the emission aperture is provided as a variable emission aperture by the adjustment plate.

According to an embodiment of the present disclosure, a substrate processing apparatus includes a process chamber having a substrate processing space defined therein, a substrate support unit configured to support a substrate in the substrate processing space, and an antenna unit configured to provide microwaves for heat treatment of the substrate supported by the substrate support unit. The antenna unit includes an antenna disposed above the substrate support unit, the antenna having a plurality of wave emission apertures formed therein to emit the microwaves from the plurality of wave emission apertures toward the substrate located below the antenna, and an adjustment plate configured to control an emission range of the microwaves through movement thereof relative to at least one emission aperture among the plurality of wave emission apertures, wherein the emission aperture is provided as a variable emission aperture by the adjustment plate.

In the substrate processing apparatus according to the embodiment of the present disclosure, the adjustment plate may be provided at the antenna so as to be horizontally movable and to control the emission range of the microwaves by partially shielding the emission aperture or releasing partial shielding of the emission aperture in accordance with a horizontal movement direction thereof. In this case, the adjustment plate may be inserted into a wall of the emission aperture so as to be horizontally movable. Alternatively, the adjustment plate may include a first unit plate coupled to a lower surface of the antenna so as to be horizontally movable and a second unit plate coupled to a lower surface of the first unit plate so as to be horizontally movable in a horizontal movement direction of the first unit plate.

The substrate processing apparatus according to the embodiment of the present disclosure may further include a plate drive module configured to move the adjustment plate relative to the emission aperture, a temperature detector configured to detect temperature distribution of the substrate, and a controller configured to control operation of the plate drive module based on the temperature distribution of the substrate detected by the temperature detector.

According to an embodiment of the present disclosure, a substrate processing apparatus includes a process chamber having a substrate processing space defined therein, a substrate support unit configured to support a substrate in the substrate processing space, an antenna unit configured to provide microwaves for heat treatment of the substrate supported by the substrate support unit, and a plasma generator configured to generate plasma for plasma processing of the substrate in the substrate processing space. The antenna unit includes an antenna disposed above the substrate support unit, the antenna having a plurality of wave emission apertures formed therein to emit the microwaves from the plurality of wave emission apertures toward the substrate located below the antenna, and an adjustment plate configured to control an emission range of the microwaves through movement thereof relative to at least one emission aperture among the plurality of wave emission apertures, wherein the emission aperture is provided as a variable emission aperture by the adjustment plate. The adjustment plate is provided at the antenna so as to be horizontally movable and to control the emission range of the microwaves by partially shielding the emission aperture or releasing partial shielding of the emission aperture in accordance with a horizontal movement direction thereof. The adjustment plate includes a first unit plate coupled to a lower surface of the antenna so as to be horizontally movable and a second unit plate coupled to a lower surface of the first unit plate so as to be horizontally movable in a horizontal movement direction of the first unit plate. The adjustment plate includes two adjustment plates disposed on both sides of the emission aperture so as to be opposite each other.

Solutions to solve the above problems may be concretely and clearly understood through embodiments to be described below and the accompanying drawings. In addition, various solutions other than the above solutions may be further provided.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIGS. 1A and 1B are partial cross-sectional views showing an antenna of a general substrate processing apparatus;

FIG. 2 is a view schematically showing the configuration of a substrate processing apparatus according to a first embodiment of the present disclosure;

FIG. 3 is a half cross-sectional view of an antenna of an antenna unit shown in FIG. 2 when viewed from above;

FIGS. 4A, 4B, 5A, 5B, 6A, 6B, 7A to 7D, and 8A to 8D are views showing the configuration of various examples of a variable emission aperture of the antenna unit shown in FIG. 2; and

FIG. 9 is a view schematically showing the configuration of a substrate processing apparatus according to a second embodiment of the present disclosure.

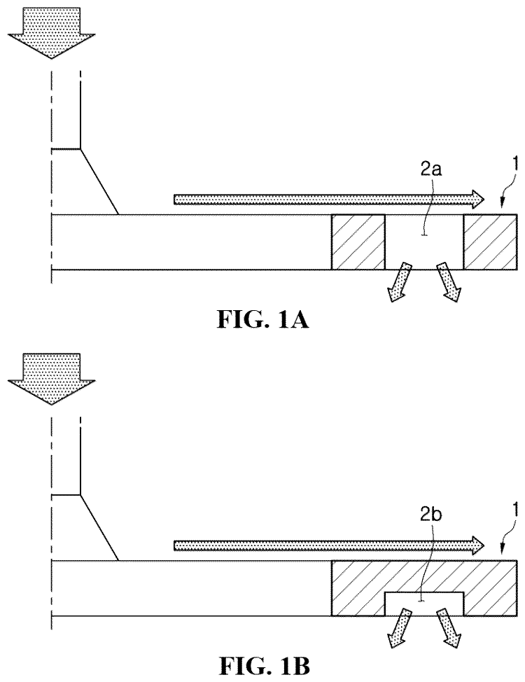

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In the following description of the embodiments of the present disclosure, a detailed description of known functions or configurations incorporated herein will be omitted when it may unnecessarily obscure the subject matter of the present disclosure. Throughout the drawings, parts performing similar functions and operations are denoted by the same reference numerals.

At least some of the terms used in this specification are terms defined taking into consideration the functions obtained in accordance with the present disclosure, and may be changed in accordance with the intention of users or operators or usual practice. Therefore, the definitions of these terms should be determined based on the total content of this specification. Additionally, the term “comprise”, “include”, or “have” described herein should be interpreted not to exclude other elements but to further include such other elements unless mentioned otherwise. Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween.

In the drawings, the sizes or shapes of elements and thicknesses of lines may be exaggerated for clarity and convenience of description.

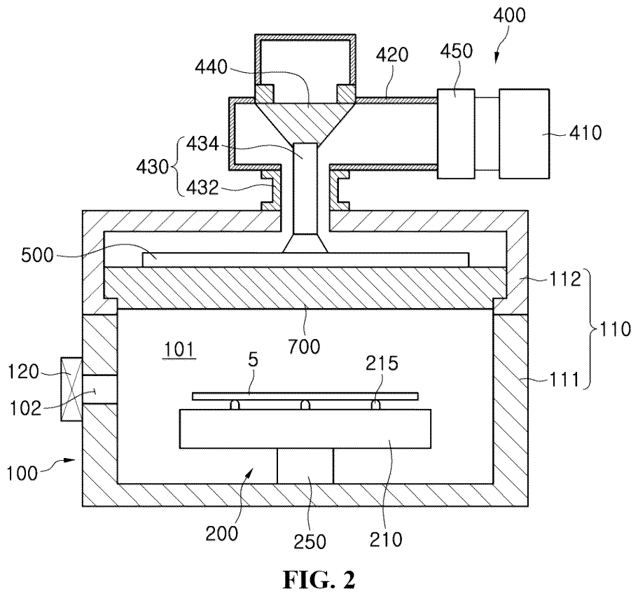

FIG. 2 is a view schematically showing the configuration of a substrate processing apparatus according to a first embodiment of the present disclosure. The substrate processing apparatus according to the first embodiment of the present disclosure may perform a heat treatment process for modification, annealing, preheating, etc. of a substrate as a substrate processing process. Referring to FIG. 2, the substrate processing apparatus according to the first embodiment of the present disclosure includes a process chamber 100, a substrate support unit 200, microwave heat treatment device 400 and 500, and a dielectric window 700 (a microwave transmitting member). Among these components, the microwave heat treatment device 400 and 500 may provide microwaves for the heat treatment process.

The process chamber 100 is configured to define a substrate processing space 101 therein and to be able to block the substrate processing space 101 from the outside in order to perform the substrate processing process.

The process chamber 100 includes a chamber body 110 formed in a cylindrical shape. The chamber body 110 includes a chamber body 111 having an open top and an empty space therein and a chamber cover 112 disposed on the chamber body 111 to cover the open top of the chamber body 111. The space in the chamber body 110 defined by the chamber body 111 and the chamber cover 112 is the substrate processing space 101. For example, the chamber body 111 may be made of metal such as aluminum (Al). Microwaves introduced into the substrate processing space 101 in order to perform the heat treatment process as the substrate processing process may be reflected by the chamber body 111 made of metal in the substrate processing space 101. The chamber cover 112 may seal the open top of the chamber body 111.

The process chamber 100 has a substrate loading/unloading port 102. The substrate loading/unloading port 102 is formed to communicate with the substrate processing space 101 in the chamber body 110, and is opened and closed by a loading/unloading port opening/closing unit 120 such as a gate valve. In detail, the substrate loading/unloading port 102 may be disposed in a wall of the chamber body 111. A substrate 5 may be introduced into the substrate processing space through the substrate 101 loading/unloading port 102 to be processed, and may be discharged to the outside of the chamber body 110 through the substrate loading/unloading port 102 after processing. The substrate loading/unloading port 102 may be kept closed by the loading/unloading port opening/closing unit 120 during the substrate processing process.

The substrate support unit 200 is configured to support the substrate 5 in the substrate processing space 101. The substrate support unit 200 includes a substrate support member 210 having a plurality of support pins 215 protruding upward and a substrate lifting module 250 configured to generate drive force to move the substrate support member 210 up and down. The substrate 5 is placed on the substrate support member 210 having a disc shape. The substrate 5 is supported by the plurality of support pins 215.

The substrate support unit 200 further includes a substrate chuck (not shown) configured to chuck the substrate 5 to fix the position of the substrate 5. For example, the substrate chuck may be provided as a chuck configured to mechanically chuck the substrate 5 with respect to the substrate support member 210. Depending on implementation conditions, the substrate support unit 200 may not include the substrate chuck, and the substrate 5 may undergo the substrate processing process in a state of being freely placed on the substrate support member 210.

The microwave heat treatment device 400 and 500 includes a microwave applying unit 400 and an antenna unit 500. Here, the microwave applying unit 400 applies microwaves to the antenna unit 500, and the antenna unit 500 introduces microwaves from the microwave applying unit 400 into the substrate processing space 101.

The microwave applying unit 400 includes a microwave generator 410 configured to generate microwaves, first and second waveguides 420 and 430 configured to transmit microwaves generated by the microwave generator 410 to the antenna unit 500, a phase shifter 440 disposed between the first waveguide 420 and the second waveguide 430, and a matching network 450 disposed in the first waveguide 420.

The first waveguide 420 is connected to the microwave generator 410, and has a passage: formed therein so as to extend in the longitudinal direction of the first waveguide 420. The microwaves generated by the microwave generator 410 are transmitted to the phase shifter 440 along the first waveguide 420.

The second waveguide 430 includes an outer conductor 432 connected to the first waveguide 420 and an inner conductor 434 disposed in the outer conductor 432.

The outer conductor 432 extends downward from an end portion of the first waveguide 420, and has a passage formed therein so as to extend in the longitudinal direction of the outer conductor 432. The upper end portion of the outer conductor 432 is connected to the lower portion of the first waveguide 420. The lower end portion of the outer conductor 432 is connected to the upper portion of the chamber cover 112.

The inner conductor 434 is formed in a rod shape and is disposed such that the longitudinal direction thereof is parallel to the vertical direction. The upper end portion of the inner conductor 434 is connected to the lower end portion of the phase shifter 440, and the lower end portion of the inner conductor 434 is coupled to the antenna unit 500 in a state of being located in the process chamber 100.

The microwaves from the first waveguide 420 may be changed in phase by the phase shifter 440, and may then be transmitted to the antenna 500 along the second waveguide 430. The phase shifter 440 is disposed at a connection point between the first waveguide 420 and the second waveguide 430. The phase shifter 440 may be formed in a cone shape with a pointed bottom. The phase shifter 440 may allow the microwaves received from the first waveguide 420 to propagate to the second waveguide 430 a state in which the propagation mode thereof is converted from the transverse electric (TE) mode to the transverse electromagnetic (TEM) mode.

The matching network 450 may match the microwaves propagating through the first waveguide 420 from the microwave generator 410 to a predetermined frequency.

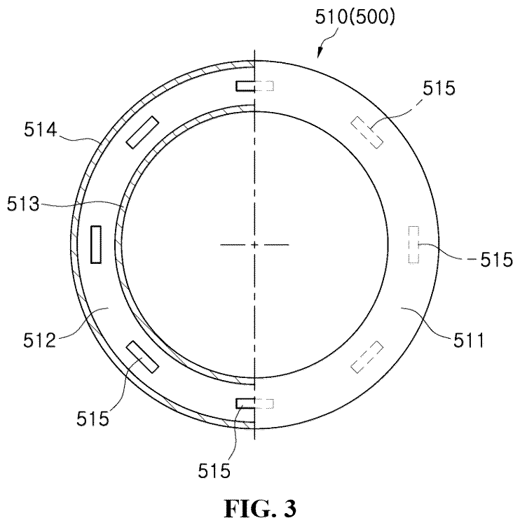

The antenna unit 500 is disposed above the substrate support unit 200 so as to face the substrate 5 supported by the substrate support unit 200. Referring to FIG. 3, the antenna unit 500 includes an antenna 510 having a circular structure. FIG. 3 shows the antenna 510 of the antenna unit 500 shown in FIG. 2. FIG. 3 is a half cross-sectional view of the antenna 510 when viewed from above.

As shown in FIG. 3, the antenna 510 includes an upper plate 511, a lower plate 512, an inner wall 513, and an outer wall 514. The antenna 510 is formed to have a plurality of wave emission apertures 515 formed therein to emit microwaves for heat treatment of the substrate 5 toward the substrate 5 located below the antenna 510.

The upper plate 511 and the lower plate 512 are formed in ring shapes corresponding to each other. The ring-shaped upper and lower plates 511 and 512 are disposed with a predetermined gap therebetween in the vertical direction so as to face each other. The inner wall 513 is formed in a ring shape and interconnects the upper plate 511 and the lower plate 512 at a relatively inner position, and the outer wall 514 is formed in a ring shape and interconnects the upper plate 511 and the lower plate 512 at a relatively outer position. The upper end portion of the inner wall 513 is formed along the inner circumference of the upper plate 511, and the lower end portion of the inner wall 513 is formed along the inner circumference of the lower plate 512. The outer wall 514 is disposed outside the inner wall 513. The upper end portion of the outer wall 514 is formed along the outer circumference of the upper plate 511, and the lower end portion of the outer wall 514 is formed along the outer circumference of the lower plate 512. Accordingly, the antenna 510 has therein a passage formed in a ring shape. That is, the antenna 510 may have therein a ring-shaped inner passage defined by the upper plate 511, the lower plate 512, the inner wall 513, and the outer wall 514.

The plurality of wave emission apertures 515 is disposed in the lower plate 512. These wave emission apertures 515 may be arranged so as to be spaced a predetermined interval from each other in the circumferential direction about the center of the antenna 510. The plurality of wave emission apertures 515 is formed in a hole shape penetrating the lower plate 512 of the antenna 510 in the vertical direction and thus has an open top and bottom. The wave emission apertures 515 may have a long slot shape. Alternatively, the plurality of wave emission apertures 515 may be formed in a groove shape concavely formed in the lower surface of the lower plate 512 of the antenna 510 and thus may have an open bottom. Alternatively, some of the plurality of wave emission apertures 515 may be formed in a hole shape penetrating the lower plate 512 of the antenna 510 in the vertical direction, and the remaining ones thereof may be formed in a groove shape concavely formed in the lower surface of the lower plate 512 of the antenna 510. The number, arrangement, and shape of the wave emission apertures 515 may be set based on test or simulation results.

The antenna 510 is made of a conductive material. The microwaves applied to the conductive antenna 510 by the microwave applying unit 400 propagate along the antenna 510 through the inner passage in the antenna 510. The microwaves propagating along the antenna 510 may be emitted downward from the plurality of wave emission apertures 515 and radiated to the substrate 5 to heat the substrate 5.

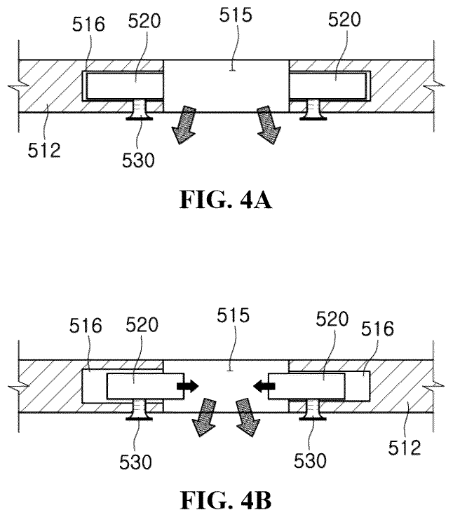

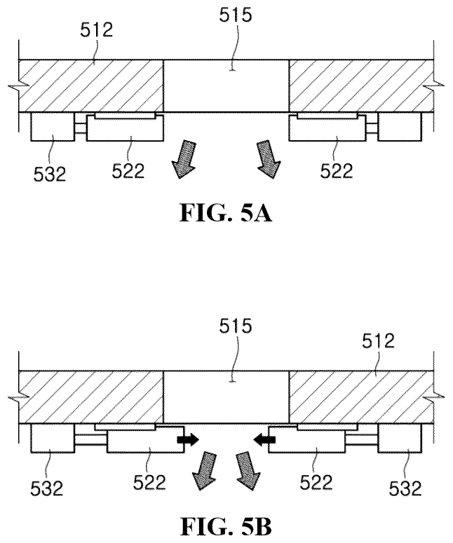

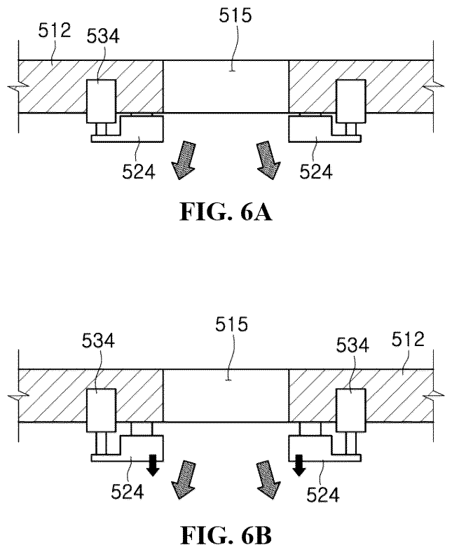

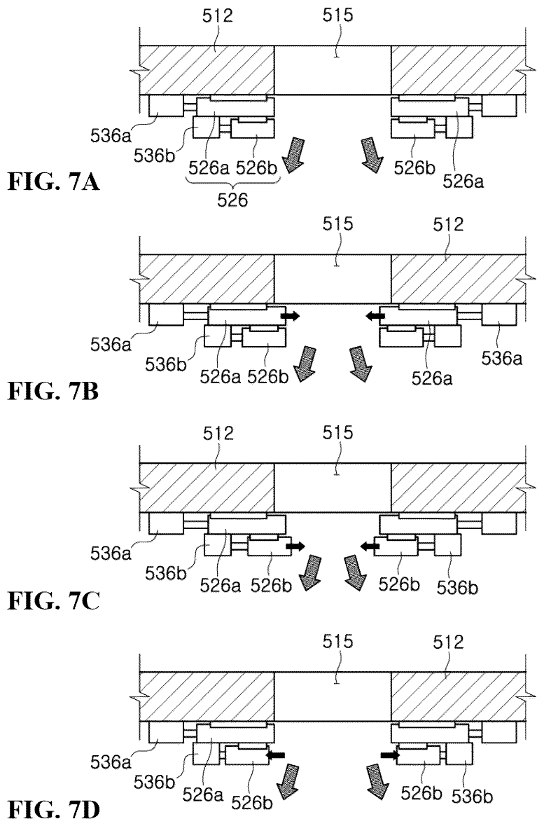

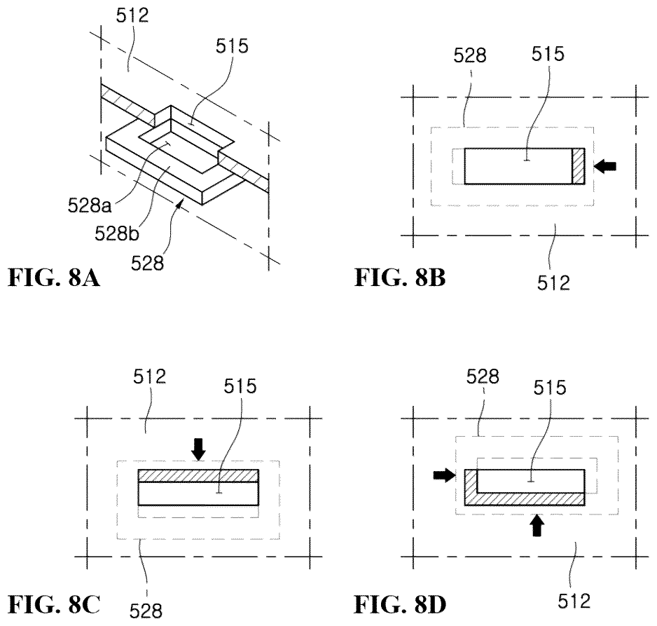

At least one of the plurality of wave emission apertures 515 is provided as a variable emission aperture to vary the emission range of the microwaves to a desired emission range through deformation thereof. To this end, the antenna unit 500 further includes an adjustment plate (refer to reference numeral 520 in FIGS. 4A and 4B, reference numeral 522 in FIGS. 5A and 5B, reference numeral 524 in FIGS. 6A and 6B, reference numeral 526 in FIGS. 7A to 7D, and reference numeral 528 in FIGS. 8A to 8D).

Various examples of the variable emission aperture provided by the adjustment plate are shown in FIGS. 4A, 4B, 5A, 5B, 6A, 6B, 7A to 7D, and 8A to 8D. The adjustment plate controls the emission range of the microwaves through movement thereof relative to the emission aperture, thereby providing the corresponding emission aperture as the variable emission aperture. The variable emission aperture may be changed in shape through movement of the adjustment plate relative to the emission aperture, and may adjust the emission range of the microwaves differently through changes in the shape thereof.

One example of the variable emission aperture will now be described with reference to FIGS. 4A and 4B. As shown in FIGS. 4A and 4B, the adjustment plate 520 is provided in the lower plate 512 of the antenna 510 so as to be horizontally movable relative to the emission aperture 515, thereby partially shielding the emission aperture 515 or releasing the partial shielding of the emission aperture 515 in accordance with the horizontal movement direction thereof.

The adjustment plate 520 may be formed in a flat plate shape. The adjustment plate 520 may be inserted into a guide groove 516 formed in the horizontal direction in a wall of the emission aperture 515 so as to be slidable along the guide groove 516. The adjustment plate 520 may protrude or retreat in accordance with the movement direction thereof. FIG. 4A shows a state in which the adjustment plate 520 is completely received in the guide groove 516 and thus the emission aperture 515 is not shielded by the adjustment plate 520. FIG. 4B shows a state in which the adjustment plate 520 slides horizontally to protrude from the guide groove 516 to the interior of the emission aperture 515 and thus the emission aperture 515 is partially shielded by the tip end portion of the adjustment plate 520. If the adjustment plate 520 protrudes (refer to FIG. 4B), the size of the variable emission aperture is reduced, and accordingly, the emission range of the microwaves through the variable emission aperture is reduced. In this way, the emission range of the microwaves may be finely adjusted. Further, the heating conditions of the substrate 5 using the microwaves may be controlled.

The adjustment plate 520 may be provided singularly or in plural. As shown in FIGS. 4A and 4B, two adjustment plates 520 may be disposed on both sides of the emission aperture 515 so as to be opposite each other. The tip end portions of the two adjustment plates 520 may protrude by the same distance or different distances. Each of the adjustment plates 520 may be fixed in position by a fixing element 530. For example, the fixing element 530 may be a fastening screw. Each of the adjustment plates 520 may be maintained in a received state or a protruding state by the fastening screw.

Another example of the variable emission aperture is shown in FIGS. 5A and 5B. Referring to FIGS. 5A and 5B, the adjustment plate 522 may be coupled to the lower surface of the lower plate 512 so as to be moved horizontally by a horizontal guide. The adjustment plate 522 may be disposed so as to move horizontally relative to the emission aperture 515, thereby partially shielding the emission aperture 515 or releasing the partial shielding of the emission aperture 515 in accordance with the horizontal movement direction thereof.

The adjustment plate 522 may be formed in a flat plate shape. FIG. 5A shows a state in which the adjustment plate 522 retreats so that the tip end of the adjustment plate 522 is aligned with the periphery of the open bottom of the emission aperture 515 and thus the emission aperture 515 is not shielded by the adjustment plate 522. FIG. 5B shows a state in which the adjustment plate 522 advances from the state shown in FIG. 5A and thus the emission aperture 515 is partially shielded by the tip end portion of the adjustment plate 522, whereby the emission range of the microwaves through the variable emission aperture is reduced. Although not shown, the adjustment plate 522 may retreat from the state shown in FIG. 5A. If the adjustment plate 522 retreats from the state shown in FIG. 5A, the variable emission aperture is deformed such that the lower portion thereof expands, thereby increasing the emission range of the microwaves through the variable emission aperture.

The adjustment plate 522 may be provided singularly or in plural. As shown in FIGS. 5A and 5B, two adjustment plates 522 may be disposed on both sides of the emission aperture 515 so as to be opposite each other. The tip end portions of the two adjustment plates 522 may protrude by the same distance or different distances.

Each of the adjustment plates 522 may be moved horizontally and fixed in position by a plate drive module 532 such as a linear actuator.

Although not shown, a temperature detector configured to detect the temperature distribution of the substrate 5 may be provided. In addition, a controller configured to independently control operation of the plate drive module 532 based on the temperature distribution of the substrate 5 detected by the temperature detector may be provided. Accordingly, the emission range of the microwaves may be finely adjusted in an automatic manner. Further, the heating conditions of the substrate 5 using the microwaves may be optimally controlled. For example, the temperature detector may include a pyrometer, a large-area two-dimensional (2D) camera, or a fiber Bragg grating (FBG) sensor. Alternatively, the operation of the plate drive module 532 may be controlled based on data of the matching network 450.

Still another example of the variable emission aperture is shown in FIGS. 6A and 6B. Referring to FIGS. 6A and 6B, the adjustment plate 524 may be coupled to the lower surface of the lower plate 512 so as to be moved vertically by a vertical guide. The adjustment plate 524 may be disposed so as to move vertically relative to the emission aperture 515, thereby moving away from or toward the emission aperture 515 in accordance with the vertical movement direction thereof.

The adjustment plate 524 may be formed such that the tip end thereof has a vertical surface aligned with the periphery of the open bottom of the emission aperture 515. FIG. 6A shows a state in which the adjustment plate 524 ascends toward the emission aperture 515, whereby the length of the variable emission aperture in the vertical direction is relatively reduced and the distance from the variable emission aperture to the substrate 5 increases. In this state, the emission range of the microwaves with respect to the substrate 5 relatively increases. In other words, the range within which the microwaves are directly radiated to the substrate 5 increases. FIG. 6B shows a state in which the adjustment plate 524 descends away from the emission aperture 515, whereby the length of the variable emission aperture in the vertical direction is relatively increased and the distance from the variable emission aperture to the substrate 5 decreases. In this state, the emission range of the microwaves with respect to the substrate 5 relatively decreases.

The adjustment plate 524 may be provided singularly or in plural. As shown in FIGS. 6A and 6B, two adjustment plates 524 may be disposed on both sides of the emission aperture 515 so as to be opposite each other. Depending on implementation conditions, the adjustment plate 524 may be formed such that the vertical surface thereof is not aligned with the periphery of the open bottom of the emission aperture 515.

Each of the adjustment plates 524 may be moved vertically and fixed in position by any (e.g., 534) of various plate drive modules, such as a linear actuator. The plate drive module 534 may be independently controlled in a manner identical or similar to that of the plate drive module 532 shown in FIGS. 5A and 5B.

Still another example of the variable emission aperture is shown in FIGS. 7A to 7D. Referring to FIGS. 7A to 7D, the adjustment plate 526 includes a first unit plate 526a coupled to the lower surface of the lower plate 512 so as to be moved horizontally by a first horizontal guide and a second unit plate 526b coupled to the lower surface of the first unit plate 526a so as to be moved horizontally by a second horizontal guide. The first unit plate 526a may be disposed so as to move horizontally relative to the emission aperture 515, thereby partially shielding the emission aperture 515 or releasing the partial shielding of the emission aperture 515 in accordance with the horizontal movement direction thereof. The second unit plate 526b may move horizontally in the same direction as the first unit plate 526a.

The first unit plate 526a and the second unit plate 526b may be formed in a flat plate shape. FIG. 7A shows a state in which the tip end of the first unit plate 526a is aligned with the periphery of the open bottom of the emission aperture 515 and the tip end of the second unit plate 526b is aligned with the tip end of the first unit plate 526a, whereby the emission aperture 515 is not shielded by the adjustment plate 526. FIG. 7B shows a state in which the first unit plate 526a advances from the state shown in FIG. 7A and thus the second unit plate 526b advances identically, whereby the emission aperture 515 is partially shielded by the tip end portion of the adjustment plate 526. In this state, the emission range of the microwaves through the variable emission aperture is reduced. FIG. 7C shows a state in which the second unit plate 526b advances from the state shown in FIG. 7B, whereby the emission aperture 515 is further shielded by the tip end portion of the second unit plate 526b. In this state, the emission range of the microwaves through the variable emission aperture is further reduced. FIG. 7D shows a state in which the second unit plate 526b retreats from the state shown in FIG. 7A, whereby the variable emission aperture is deformed such that the lower portion thereof expands. In this state, the emission range of the microwaves through the variable emission aperture is increased. Although not shown, the first unit plate 526a may retreat from the state shown in FIG. 7A or the state shown in FIG. 7D.

The adjustment plate 526 may be provided singularly or in plural. As shown in FIGS. 7A to 7D, two adjustment plates 526, each of which includes unit plates 526a and 526b, may be disposed on both sides of the emission aperture 515 so as to be opposite each other. Depending on implementation conditions, the adjustment plate 526 may include three or more unit plates.

In the adjustment plate 526, the first unit plate 526a may be moved horizontally and fixed in position by a first plate drive module 536a, and the second unit plate 526b may be moved horizontally and fixed in position by a second plate drive module 536b. The first and second plate drive modules 536a and 536b may be independently controlled in a manner identical or similar to that of the plate drive module 532 shown in FIGS. 5A and 5B.

On the other hand, in the adjustment plate 526, the first unit plate 526a or the second unit plate 526b may be provided so as to be moved vertically by a plate drive module for vertical driving, rather than being moved horizontally.

Still another example of the variable emission aperture is shown in FIGS. 8A to 8D. Referring to FIG. 8A, the adjustment plate 528 is coupled to the lower surface of the lower plate 512 so as to be moved in a first horizontal direction and a second horizontal direction perpendicular to the first horizontal direction by a horizontal guide. The adjustment plate 528 is formed to have an open area 528a formed corresponding to the emission aperture 515 and a shielding area 528b formed around the open area 528a.

The adjustment plate 528 may be formed in a flat plate shape. FIG. 8A shows a state in which the open area 528a of the adjustment plate 528 is completely aligned with the emission aperture 515 and thus the emission aperture 515 is not shielded by the shielding area 528b of the adjustment plate 528. FIG. 8B shows a state in which the adjustment plate 528 moves in the first horizontal direction from the state shown in FIG. 8A and thus a portion of the emission aperture 515 in the first horizontal direction is shielded by the shielding area 528b of the adjustment plate 528. FIG. 8C shows a state in which the adjustment plate 528 moves in the second horizontal direction perpendicular to the first horizontal direction from the state shown in FIG. 8A and thus a portion of the emission aperture 515 in the second horizontal direction is shielded by the shielding area 528b of the adjustment plate 528. FIG. 8D shows a state in which the adjustment plate 528 moves in the first horizontal direction and the second horizontal direction from the state shown in FIG. 8A and thus both a portion of the emission aperture 515 in the first horizontal direction and a portion of the emission aperture 515 in the second horizontal direction are shielded by the shielding area 528b of the adjustment plate 528. A portion of the emission aperture 515 shielded by the shielding area 528b is indicated by the oblique lines.

Although not shown, the adjustment plate 528 may be moved in the first horizontal direction by a first horizontal drive module and may be moved in the second horizontal direction by a second horizontal drive module. The first and second horizontal drive modules may be independently controlled in a manner identical or similar to that of the plate drive module 532 shown in FIGS. 5A and 5B.

On the other hand, the adjustment plate 528 may be provided so as to be moved vertically by a plate drive module for vertical driving, rather than being moved in the first horizontal direction or the second horizontal direction.

Referring again to FIG. 2, the dielectric window 700 is disposed under the antenna unit 500. The dielectric window 700 is formed in a disc shape having a predetermined thickness. Alternatively, the dielectric window 700 may be provided to constitute the chamber cover 112. The microwaves emitted from the antenna 510 pass through the dielectric window 700, and then are introduced into the substrate processing space 101 in the process chamber 100.

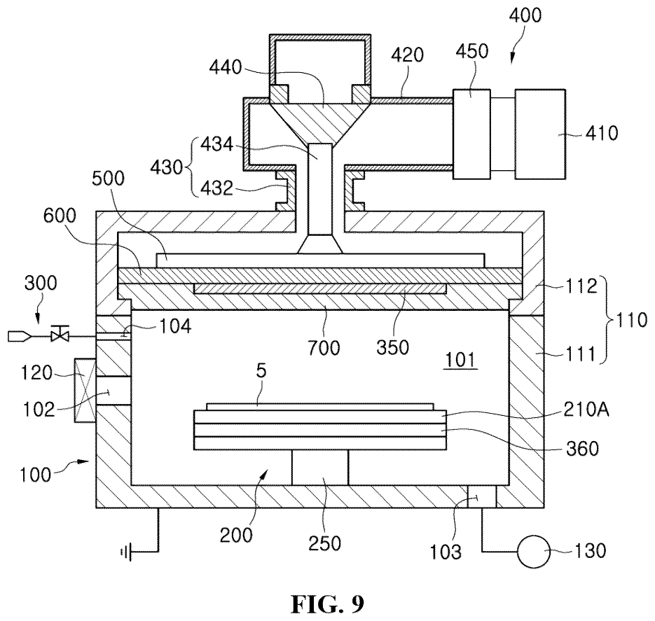

A substrate processing apparatus according to a second embodiment of the present disclosure is shown in FIG. 9. Referring to FIG. 9, the substrate processing apparatus according to the second embodiment of the present disclosure is configured to perform a heat treatment process and a plasma processing process, which are different substrate processing processes, in the substrate processing space 101 in the process chamber 100. For example, the substrate processing apparatus according to the second embodiment of the present disclosure may operate to perform only one of the heat treatment process and the plasma processing process on the substrate 5 and then discharge the substrate 5 out of the substrate processing space 101. Alternatively, the substrate processing apparatus according to the second embodiment of the present disclosure may operate to sequentially perform one (e.g., the heat treatment process) of the heat treatment process and the plasma processing process and the other (e.g., the plasma processing process) thereof and then discharge the substrate 5 out of the substrate processing space 101. Of course, the heat treatment process and the plasma processing process may be repeated in a set order. The plasma processing process may be atomic layer deposition (ALD), atomic layer etching (ALE), chemical vapor deposition (CVD), or the like.

The substrate processing apparatus according to the second embodiment of the present disclosure has the same configuration as the substrate processing apparatus according to the first embodiment of the present disclosure, except for the following configuration.

The chamber body 110 of the process chamber 100 may be grounded. The process chamber 100 has an exhaust port 103. The exhaust port 103 is provided in the chamber body 110 so as to communicate with the substrate processing space 101, and is connected to an exhaust unit 130.

The exhaust port 103 is disposed in the bottom of the chamber body 111. The exhaust unit 130 includes an exhaust line connected to the exhaust port 103 and a vacuum pump mounted on the exhaust line, and performs exhaust operation on the substrate processing space 101. Due to the exhaust unit 130, the substrate processing space 101 may be reduced in pressure so that the substrate processing process is performed in the state in which the pressure of the substrate processing space 101 is maintained to be lower than the atmospheric pressure. In addition, by-products generated during the substrate processing process or gases remaining in the substrate processing space 101 may be discharged to the outside.

In the substrate support unit 200, a substrate support member 210A is provided as an electrostatic chuck (ESC) that chucks the substrate 5 using electrostatic force. The electrostatic chuck 210A may be formed in a disc shape having a predetermined thickness due to a dielectric substance, and may include a chuck electrode (not shown). When power is supplied to the chuck electrode, a predetermined amount of electrostatic force is generated between the substrate 5 placed on the electrostatic chuck 210A and the chuck electrode embedded in the electrostatic chuck 210A, whereby the substrate 5 may be maintained in a state of being chucked on the electrostatic chuck 210A during the substrate processing process.

The substrate processing apparatus according to the second embodiment of the present disclosure includes a plasma generator to perform the plasma processing process. The plasma generator includes a process gas supply unit 300 configured to supply process gas to the substrate processing space 101 through a process gas supply port 104 provided in the chamber body 111 of the chamber body 110 and a plasma source configured to form plasma from the process gas supplied to the substrate processing space 101 by the process gas supply unit 300. The plasma source is a capacitively coupled plasma (CCP) source including an upper electrode member 350 provided between the antenna unit 500 and the dielectric window 700 and a lower electrode member 360 provided in the substrate support unit 200.

The upper electrode member 350 and the lower electrode member 360 face each other. The upper electrode member 350 is provided as a transparent electrode member made of a material such as indium tin oxide (ITO) and thus may transmit microwaves from the antenna unit 500. The lower electrode member 360 supports the electrostatic chuck 210A.

An insulator 600 is interposed between the upper electrode member 350 and the antenna unit 500 in order to electrically isolate the upper electrode member 350 and the antenna unit 500 from each other. The insulator 600 may be made of an insulative material capable of transmitting microwaves (e.g., quartz, ceramic, or microwave-transparent plastic).

As is apparent from the above description, according to the embodiment of the present disclosure, an antenna unit has a plurality of wave emission apertures formed therein to emit microwaves for heat treatment of a substrate toward the substrate located below the antenna unit. In addition, at least one of the plurality of wave emission apertures is provided as a variable emission aperture to control the emission range of the microwaves through slight deformation thereof.

Accordingly, it is possible to precisely adjust the emission range of the microwaves to a desired emission range using the variable emission aperture.

The effects achievable through the present disclosure are not limited to the above-mentioned effects, and other effects not mentioned herein will be clearly understood by those skilled in the art from this specification and the accompanying drawings.

While the present disclosure has been described above, the present disclosure is not limited to the disclosed embodiments and the accompanying drawings, and various modifications and variations can be made by those skilled in the art without departing from the technical spirit of the present disclosure. In addition, the technical features described in the embodiments of the present disclosure may be independently implemented, or two or more technical features may be combined.

What is claimed is:

1. An antenna unit comprising:
an antenna having a plurality of wave emission apertures formed therein to emit microwaves for heat treatment of a substrate toward the substrate located below the antenna; and
an adjustment plate configured to control an emission range of the microwaves through movement thereof relative to at least one emission aperture among the plurality of wave emission apertures,
wherein the at least one emission aperture is provided as a variable emission aperture by the adjustment plate.

2. The antenna unit as claimed in claim 1,
wherein the adjustment plate is provided at the antenna so as to be horizontally movable and to control the emission range of the microwaves by partially shielding the at least one emission aperture or releasing partial shielding of the at least one emission aperture in accordance with a horizontal movement direction of the adjustment plate.

3. The antenna unit as claimed in claim 2,
wherein the adjustment plate comprises two adjustment plates, and
wherein the two adjustment plates are disposed on both sides of the at least one emission aperture so as to be opposite each other.

4. The antenna unit as claimed in claim 2,
wherein the adjustment plate is inserted into a wall of the at least one emission aperture so as to be horizontally movable.

5. The antenna unit as claimed in claim 2,
wherein the adjustment plate is coupled to a lower surface of the antenna so as to be horizontally movable.

6. The antenna unit as claimed in claim 2,
wherein the adjustment plate comprises:
a first unit plate coupled to a lower surface of the antenna so as to be horizontally movable; and
a second unit plate coupled to a lower surface of the first unit plate so as to be horizontally movable in a horizontal movement direction of the first unit plate.

7. The antenna unit as claimed in claim 6,
wherein the adjustment plate comprises two adjustment plates, each comprising the first unit plate and the second unit plate, and
wherein the two adjustment plates are disposed on both sides of the at least one emission aperture so as to be opposite each other.

8. The antenna unit as claimed in claim 2,
wherein the adjustment plate comprises:
an open area formed corresponding to the at least one emission aperture; and
a shielding area formed around the open area.

9. The antenna unit as claimed in claim 1,
wherein the adjustment plate is provided at the antenna so as to be vertically movable and to control the emission range of the microwaves by moving away from or toward the at least one emission aperture in accordance with a vertical movement direction thereof.

10. The antenna unit as claimed in claim 9,
wherein the adjustment plate is coupled to a lower surface of the antenna so as to be vertically movable.

11. The antenna unit as claimed in claim 9,
wherein the adjustment plate comprises two adjustment plates, and
wherein the two adjustment plates are disposed on both sides of the at least one emission aperture so as to be opposite each other.

12. The antenna unit as claimed in claim 9,
wherein the adjustment plate comprises an open area aligned with the at least one emission aperture.

13. The antenna unit as claimed in claim 1,
wherein the adjustment plate comprises:
a first unit plate provided at the antenna so as to be horizontally movable and to partially shield the at least one emission aperture or release partial shielding of the at least one emission aperture in accordance with a horizontal movement direction of first unit plate; and
a second unit plate provided on a lower surface of the first unit plate so as to be vertically movable and to move away from or toward the first unit plate in accordance with a vertical movement direction thereof.

14. The antenna unit as claimed in claim 1, further comprising a plate drive module configured to move the adjustment plate relative to the at least one emission aperture.

15. A substrate processing apparatus comprising:
a process chamber having a substrate processing space defined therein;
a substrate support unit configured to support a substrate in the substrate processing space; and
an antenna unit configured to provide microwaves for heat treatment of the substrate supported by the substrate support unit,
wherein the antenna unit comprises:
an antenna disposed above the substrate support unit, the antenna having a plurality of wave emission apertures formed therein to emit the microwaves from the plurality of wave emission apertures toward the substrate located below the antenna; and
an adjustment plate configured to control an emission range of the microwaves through movement thereof relative to at least one emission aperture among the plurality of wave emission apertures, and
wherein the at least one emission aperture is provided as a variable emission aperture by the adjustment plate.

16. The substrate processing apparatus as claimed in claim 15,
wherein the adjustment plate is provided at the antenna so as to be horizontally movable and to control the emission range of the microwaves by partially shielding the at least one emission aperture or releasing partial shielding of the at least one emission aperture in accordance with a horizontal movement direction thereof.

17. The substrate processing apparatus as claimed in claim 16,
wherein the adjustment plate is inserted into a wall of the at least one emission aperture so as to be horizontally movable.

18. The substrate processing apparatus as claimed in claim 16,
wherein the adjustment plate comprises:
a first unit plate coupled to a lower surface of the antenna so as to be horizontally movable; and
a second unit plate coupled to a lower surface of the first unit plate so as to be horizontally movable in a horizontal movement direction of the first unit plate.

19. The substrate processing apparatus as claimed in claim 15, further comprising:
a plate drive module configured to move the adjustment plate relative to the at least one emission aperture;
a temperature detector configured to detect temperature distribution of the substrate; and
a controller configured to control operation of the plate drive module based on the temperature distribution of the substrate detected by the temperature detector.

20. A substrate processing apparatus comprising:
a process chamber having a substrate processing space defined therein;
a substrate support unit configured to support a substrate in the substrate processing space;
an antenna unit configured to provide microwaves for heat treatment of the substrate supported by the substrate support unit; and
a plasma generator configured to generate plasma for plasma processing of the substrate in the substrate processing space,
wherein the antenna unit comprises:
an antenna disposed above the substrate support unit, the antenna having a plurality of wave emission apertures formed therein to emit the microwaves from the plurality of wave emission apertures toward the substrate located below the antenna; and
an adjustment plate configured to control an emission range of the microwaves through movement thereof relative to at least one emission aperture among the plurality of wave emission apertures,
wherein the at least one emission aperture is provided as a variable emission aperture by the adjustment plate,
wherein the adjustment plate is provided at the antenna so as to be horizontally movable and to control the emission range of the microwaves by partially shielding the at least one emission aperture or releasing partial shielding of the at least one emission aperture in accordance with a horizontal movement direction of the adjustment plate,
wherein the adjustment plate comprises:
a first unit plate coupled to a lower surface of the antenna so as to be horizontally movable; and
a second unit plate coupled to a lower surface of the first unit plate so as to be horizontally movable in a horizontal movement direction of the first unit plate, and
wherein the adjustment plate comprises two adjustment plates disposed on both sides of the at least one emission aperture so as to be opposite each other.
